(19) United States
(12) Patent Application Publication
(10) Pub. No.: US 2012/0298992 A1
(43) Pub. Date: Nov. 29, 2012

(54) TEST LAYOUT STRUCTURE

(76) Inventors: Chin-Te Kuo, New Taipei City (TW); Yi-Nan Chen, Taipei City (TW); Hsien-Wen Liu, Taoyuan County (TW)

(21) Appl. No.: 13/117,126

(22) Filed: May 26, 2011

(51) Int. Cl. H01L 23/544

(52) U.S. Cl. 257/48; 257/E23.179

(57) ABSTRACT

A test layout structure includes a substrate, a first oxide region of a first height, a second oxide region of a second height, a plurality of border regions, and a test layout pattern. The first oxide region is disposed on the substrate. The second oxide region is also disposed on the substrate and adjacent to the first oxide region. The first height is substantially different from the second height. A plurality of border regions are disposed between the first oxide region and the second oxide region. The test layout pattern includes a plurality of individual sections. A test region is disposed between two of the adjacent individual sections which are parallel to each other.

### BACKGROUND OF THE INVENTION

1. Field of the Invention

The present invention generally relates to a test layout structure. In particular, the present invention is directed to a test layout structure having at least two oxide layers of different heights utilized for representing corresponding regions in other areas and for detecting any possible bridge leak issues.

2. Description of the Prior Art

A semiconductor device usually uses poly-silicon to serve as a conductive material to form elements such as gate structures. Since the poly-silicon has to form certain required patterns, an etching step is usually employed to pattern the poly-silicon layer.

Conventionally, a poly-silicon layer is often formed on a substrate with two oxide layers of different heights. FIGS. 1-2 illustrate conventional etching of a poly-silicon layer on a substrate with two oxide layers of different heights. For example, as shown in FIG. 1, a poly-silicon layer 20 is formed on a substrate 10 with a thin oxide layer 30, a shallow trench isolation layer 40 and a thick oxide layer 50.

As shown in FIG. 2, the poly-silicon layer 20 respectively on the thin oxide layer 10 and the thick oxide layer 12 is partially removed to form a poly line 21 on the shallow trench isolation layer 40. The poly-silicon layer 20 on the thin oxide layer 30 and the thick oxide layer 50 is removed by a dry etching procedure to form the needed poly line 21. The etching end is usually determined by the oxide signal . For example, it is a blind end determined by the etching time in seconds.

Since there is an abrupt gap 60 at the border of the thin oxide layer 30 and the shallow trench isolation layer 40, the time required for the total removal of the poly-silicon layer 20 on the thin oxide layer 30 must be longer than that for the thick oxide layer 50.

Due to this abrupt gap 60, it is almost impossible to determine the end point of the etching procedure for the poly-silicon layer 20 on the thin oxide layer 30 precisely. Further, there will almost always be some remaining poly-silicon 22 left at the abrupt gap 60. This remaining poly-silicon 22 is responsible for a potential problem known as a bridge leak issue. In still another aspect, there may be various different abrupt gaps 60 disposed between any two adjacent thin oxide layer 30 and shallow trench isolation layer 40 on a wafer (not shown), which makes the bridge leak issue even more complicated and much harder to detect and solve.

As a result, a novel solution is still needed to address the problem of remaining poly-silicon in different abrupt gaps disposed between any two adjacent thin oxide layer and thick oxide layer on a wafer.

### SUMMARY OF THE INVENTION

Given the above, the present invention proposes a test layout structure to simulate poly lines crossing various abrupt gaps disposed between two adjacent thin oxide layer and thick oxide layer (shallow trench isolation layer). This test layout structure is a product-like pattern and capable of representing various scenarios of poly lines crossing various abrupt gaps after the etching procedure, representing the corresponding regions in other areas such as the active areas, and capable of detecting any possible bridge leak issues. This test layout structure may also be used to monitor the etching procedure in order to obtain a better etching end.

The test layout structure of the present invention includes a substrate, a first oxide region of a first height, a second oxide region of a second height, a plurality of border regions, and a test layout pattern. The first oxide region is disposed on the substrate and has a first rectangular shape. The second oxide region is also disposed on the substrate, adjacent to the first oxide region and has a second rectangular shape. The first height is substantially different from the second height. A plurality of border regions are disposed between the first oxide region and the second oxide region. The test layout pattern is simultaneously disposed on both the first oxide region and the second oxide region and includes a conductive material with a plurality of individual sections. The individual sections may include a plurality of first sections and a plurality of second sections. The first sections extend along a first direction and the second sections extend along a second direction substantially perpendicular to the first direction. The test region is disposed between two of the adjacent individual sections which are parallel with each other.

In one embodiment of the present invention, the first oxide region is a high voltage region.

In another embodiment of the present invention, the second oxide region is a low voltage region.

In another embodiment of the present invention, the first height is substantially greater than the second height.

In another embodiment of the present invention, the conductive material includes poly-Si.

In another embodiment of the present invention, the test region is parallel with or perpendicular to two of the adjacent individual sections.

In another embodiment of the present invention, the individual sections are the first sections or the second sections.

In another embodiment of the present invention, one of the individual sections covers one of the border regions.

In another embodiment of the present invention, one of the individual sections is disposed on the first oxide region.

In another embodiment of the present invention, one of the individual sections is disposed on the second oxide region.

In another embodiment of the present invention, one of the border regions forms the test region.

In another embodiment of the present invention, the conductive material is disposed in the test region.

In another embodiment of the present invention, the test region is free of the conductive material.

In another embodiment of the present invention, a plurality of the first sections and a plurality of the second sections together extend along one of the first direction and the second direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 illustrate a conventional etching of a poly-silicon layer on a substrate with two oxide layers of different heights.

FIGS. 3-5 illustrate the test layout structure of the present invention.

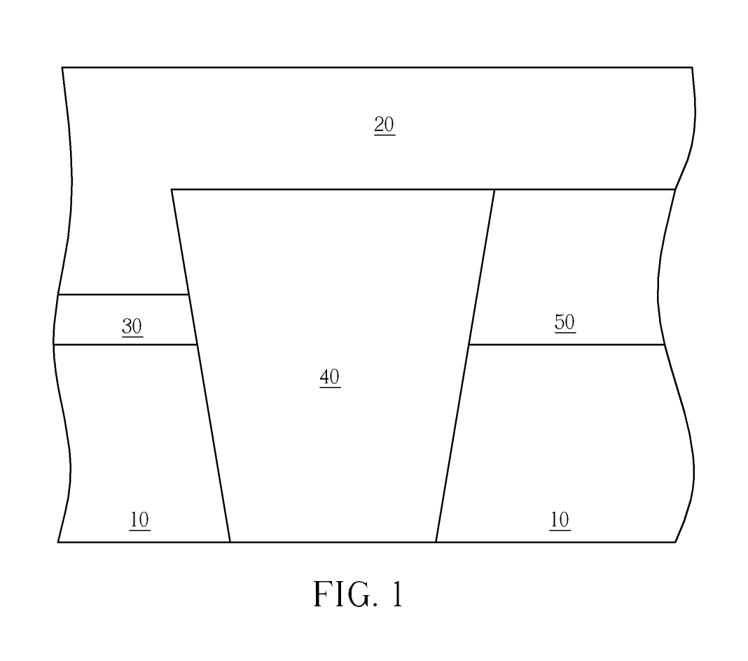

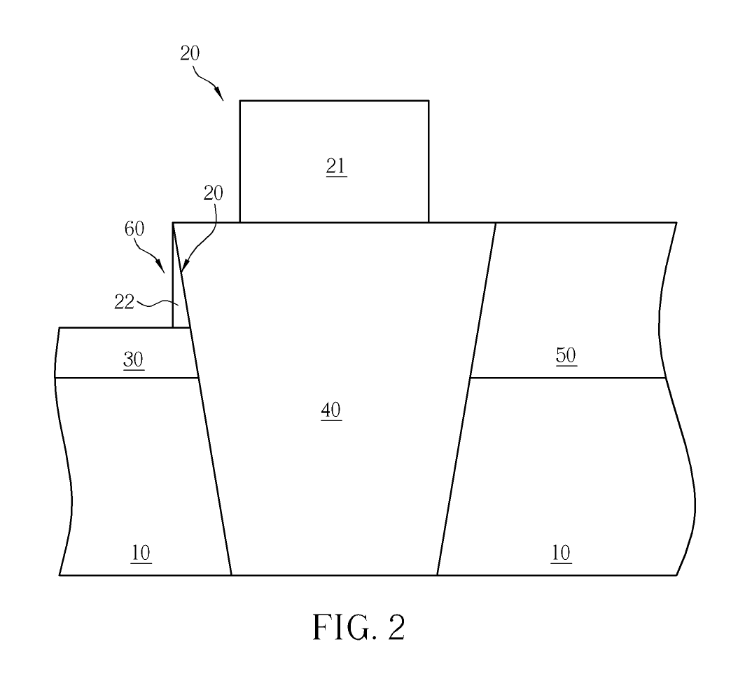

### DETAILED DESCRIPTION

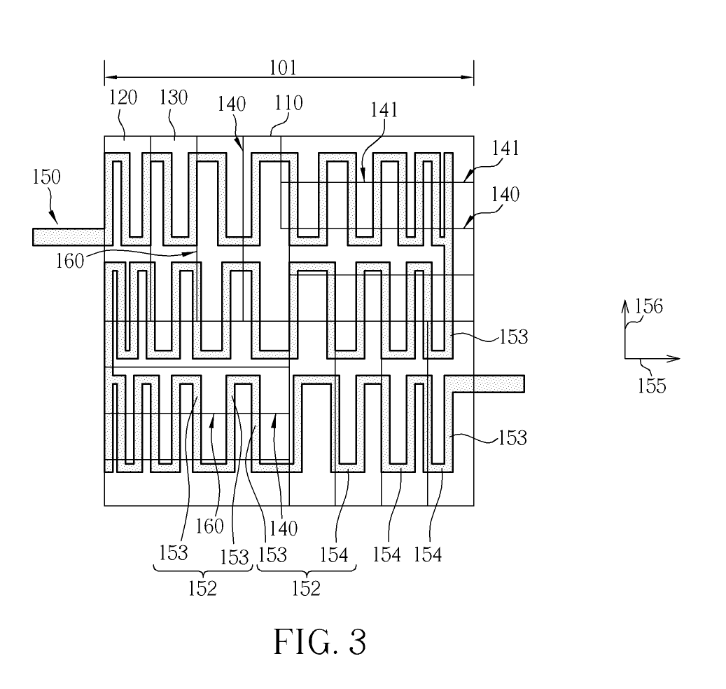

The present invention provides a test layout structure for use in WAT (wafer acceptance test). The test layout structure of the present invention may simulate poly lines crossing various abrupt gaps. The test layout structure of the present invention may represent various scenarios of poly lines crossing various abrupt gaps after the etching procedure in other areas such as the active areas and can be used to detect any possible bridge leak issues. Please refer to FIGS. 3-5, which illustrate the test layout structure of the present invention. As shown in FIG. 3, the test layout structure 100 of the present invention includes a substrate 110, a first oxide region 120 of a first height, a second oxide region 130 of a second height, a plurality of border regions 140, and a test layout pattern 150. The substrate 110 is usually a wafer including a semiconductive material, such as Si. There maybe various regions on the substrate 110, such as an active region (not shown) or a scrub line region 101. The test layout structure 100 of the present invention is usually located within the scrub line region 101.

The first oxide region 120 is disposed on the substrate 110 and has a first rectangular shape. For example, the first oxide region 120 may have the dimensions 1 μm. The second oxide region 130 is also disposed on the substrate 110 and adjacent to some of the first oxide region(s) 120. The second oxide region 130 has a second rectangular shape, too, and may have the dimensions 1.2 μm. The first rectangular shape may or may not be similar to the second oxide region 130.

One feature of the present invention is that the first height is substantially different from the second height. In one example, the first height is substantially greater than the second height. In another example, the second height is substantially greater than the first height. When the first height is substantially greater than the second height, the first oxide region 120 may serve as a high voltage region and the second oxide region 130 may serve as a low voltage region for a lower thickness.

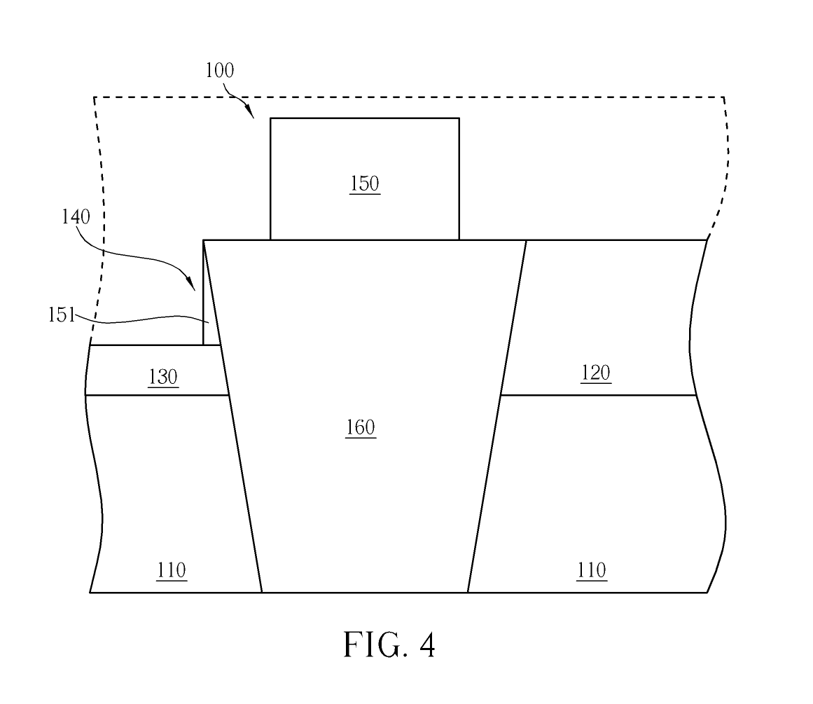

There are multiple border regions 140 which are disposed on the substrate 110. Each border region 140 is disposed between any two adjacent first oxide region 120 and second oxide region 130. If the shallow trench isolation layer (not shown) is present, the border regions 140 may be disposed between two adjacent low oxide region and shallow trench isolation layer (not shown). In other words, as shown in FIG. 4, a border region 140 always includes an abrupt gap 141 (the catching difference) across an adjacent first oxide region 120 and second oxide region 130, or adjacent low oxide region 130 and shallow trench isolation 160, which means the abrupt gap 141 crosses over from one oxide region to another oxide region of different height.

The test layout pattern 150 is also disposed on the substrate 110 and in direct contact with the first oxide region 120 and second oxide region 130. As shown in FIG. 4, the test layout pattern 150 is constructed by forming a bulky conductive material 151 on the first oxide region 120 and second oxide region 130, and then patterning the conductive material 151 using a dry etching method which is controlled by an end point signal. The conductive material 151 is usually poly-Si.

The test layout pattern 150 made of the conductive material 151 includes multiple individual sections 152. One of the individual sections may be disposed on the first oxide region 120 or disposed on the second oxide region 130. In particular, one of the individual sections 152 may cover one of the border regions 140.

Each individual section 152 may be a first section 153 and a second section 154. In other words, multiple individual sections 152 include multiple first sections 153 which extend along a first direction 155 and multiple second sections 154 which extend along a second direction 156. The first direction 155 is substantially perpendicular to the first direction 156.

Further, a test region 160 is disposed between two of the adjacent individual sections 152 which are parallel with each other. The test region 160 is perpendicular to these adjacent individual sections 152. For example, the individual sections 152 are both the first sections 153. Alternatively, the individual sections 152 are both the second sections 154.

Another feature of the present invention is that one of the border regions 140 forms the test region 160. Since the multiple individual sections 152 are constructed by forming the conductive material 151 on the first oxide region 120 and second oxide region 130 and patterning the conductive material 151 using a dry etching method, the border regions 140 as well as the test region 160 must be covered by the conductive material 151 and are formed by removing the excessive conductive material 151.

As described earlier, the dry etching method is usually controlled by an end point signal to universally represent the “ideal” end point of the etching of the conductive material 151, as shown in FIG. 4. Due to the presence of various types of abrupt gaps 141 between any two adjacent first oxide region 120 and second oxide region 130, the determination of the end point of the etching procedure for the conductive material 151 around each abrupt gap 141 is almost impossible to be universally precise, making it highly possible that there will be some remaining conductive material 151 at the abrupt gap 141.

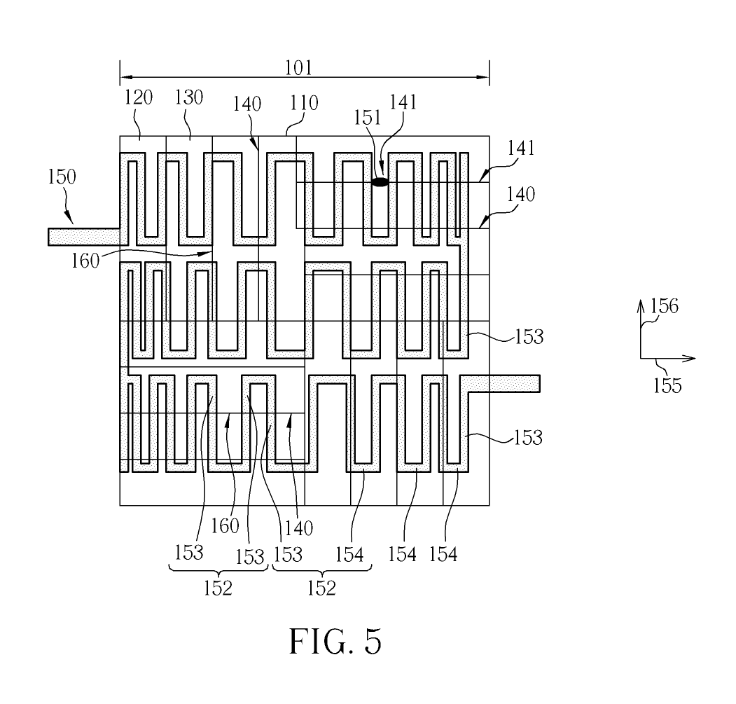

As shown in FIG. 5, when enough conductive material 151 is accumulated at the abrupt gap 141, the accumulated conductive material 151 may serve as a bridge which acts as a shortcut of the conductive path of the individual sections 152. Once a shortcut is formed, the original test layout pattern 150 is no longer counted as an actual path for a current. The original test layout pattern 150 eventually fails, and the shortcut also leads to the failure of the semiconductor device containing such layout patterns, i.e. other corresponding parts of the test layout pattern 150.

In one embodiment of the present invention, the test region 160 is free of the remaining conductive material 151, as shown in FIG. 3. When this situation occurs, the original test layout pattern 150 must have the longest conductive path and shows the highest possible electrical resistance. In another embodiment of the present invention, the test region 160 may include unremoved conductive material 151 disposed at the abrupt gap 141, as shown in FIG. 5. When there is unremoved conductive material 151 which will act as abridge of a shortcut, there must be lower total electrical resistance along the entire test layout pattern 150.

As demonstrated, the total electrical resistance along the entire test layout pattern 150 may represent whether the formation of the layout pattern 150 or the removal of the excessive conductive material 151 is exact or not. In conclusion, the test layout structure 100 is capable of representing other corresponding regions in other areas such as an active area (not shown) and detecting any possible bridge leak issues in the test layout pattern.

In another embodiment of the present invention, multiple first sections 153 and multiple second sections 154 may extend together along the first direction 155 or the second direction 156 to form a wave pattern, as shown in FIG. 3 or 5.

Those skilled in the art will readily observe that numerous modifications and alterations of the device and method may be made while retaining the teachings of the invention.

What is claimed is:

1. A test layout structure, comprising:
a substrate;
at least a first oxide region disposed on said substrate, of a first height and in a first rectangular shape;
at least a second oxide region disposed on said substrate, adjacent to said at least one first oxide region, of a second height and in a second rectangular shape, wherein there are a plurality of border regions disposed between said at least one first oxide region and said at least one second oxide region, and said first height is substantially different from said second height; and
a test layout pattern comprising a conductive material with a plurality of individual sections comprising a plurality of first sections extending along a first direction and a plurality of second sections extending along a second direction substantially perpendicular to said first direction, wherein a test region is disposed between two adjacent said individual sections that are parallel to each other.

2. The test layout structure of claim 1, wherein said first oxide region is a high voltage region.

3. The test layout structure of claim 1, wherein said second oxide region is a low voltage region.

4. The test layout structure of claim 1, wherein said first height is substantially greater than said second height.

5. The test layout structure of claim 1, wherein said conductive material comprises poly-Si.

6. The test layout structure of claim 1, wherein said test region is parallel to two adjacent said individual sections.

7. The test layout structure of claim 6, wherein said individual sections are said first sections.

8. The test layout structure of claim 6, wherein said individual sections are said second sections.

9. The test layout structure of claim 1, wherein said test region is perpendicular to two adjacent said individual sections.

10. The test layout structure of claim 9, wherein said individual sections are said first sections.

11. The test layout structure of claim 9, wherein said individual sections are said second sections.

12. The test layout structure of claim 1, wherein one of said individual sections covers one of said border regions.

13. The test layout structure of claim 1, wherein one of said individual sections is disposed on said at least one first oxide region.

14. The test layout structure of claim 1, wherein one of said individual sections is disposed on said at least one second oxide region.

15. The test layout structure of claim 1, further comprising:
a plurality of said first oxide regions.

16. The test layout structure of claim 1, further comprising:
a plurality of said second oxide regions.

17. The test layout structure of claim 1, wherein one of said border regions forms said test region.

18. The test layout structure of claim 1, wherein said test region comprises said conductive material.

19. The test layout structure of claim 1, wherein said test region is said conductive material free.

20. The test layout structure of claim 1, wherein a plurality of said first sections and a plurality of said second sections extend together along one of said first direction and said second direction.
